(19) United States
(12) Patent Application Publication
(10) Pub. No.: US 2025/0316521 A1
(43) Pub. Date: Oct. 9, 2025

(54) SEPARATING CARRIER AND DEVICE WAFER ASSEMBLIES

(71) Applicant: Qorvo US, Inc., Greensboro, NC (US)

(72) Inventors: Krishna Chetry, Richardson, TX (US); Michael Carroll, Jamestown, NC (US)

(21) Appl. No.: 19/046,795

(22) Filed: Feb. 6, 2025

Related U.S. Application Data
(60) Provisional application No. 63/631,425, filed on Apr. 8, 2024.

(51) Int. Cl. H01L 21/683; H01L 21/324

(52) U.S. Cl. CPC H01L 21/6835; H01L 21/324; H01L 2221/6834; H01L 2221/68381

(57) ABSTRACT

A process for debonding carrier and device wafer assemblies comprises providing a carrier wafer assembly and a device wafer assembly that comprises a substrate, and a device layer on the substrate. The device layer has at least one semiconductor device formed therein, and the substrate has a planar implantation zone of implant material below the device layer. The carrier wafer assembly is bonding to the device layer of the device wafer assembly with an adhesive. The substrate is annealed to weaken the substrate along the planar implantation zone. A main portion of the substrate above the planar implantation zone is separated from the device wafer assembly to form a thinned device wafer assembly. A residual portion of the substrate is removed from the thinned device wafer assembly to form a precursor.

This application claims the benefit of U.S. provisional patent application Ser. No. 63/631,425, filed Apr. 8, 2024, the disclosure of which is incorporated herein by reference in its entirety.

### FIELD OF THE DISCLOSURE

The present disclosure relates to wafer level processing in general and an approach for separating carrier and device wafer assemblies.

### BACKGROUND

Radio frequency (RF) switch devices are often fabricated on silicon-on-insulator (SOI) wafers with buried oxide. Fabricating these devices on silicon (Si) wafers and replacing the backside substrate with alternative materials promises to reduce manufacturing costs and improve device performance. However, there is a need for an efficient technique to separate the device layer from the parent Si substrate with precise control.

### SUMMARY

The present disclosure relates to debonding carrier and device wafer assemblies. The process comprises providing a carrier wafer assembly and a device wafer assembly that comprises a substrate and a device layer on the substrate. The device layer has at least one semiconductor device formed therein, and the substrate has a planar implantation zone of implant material below the device layer. The carrier wafer assembly is bonded to the device layer of the device wafer assembly with an adhesive. The substrate is annealed to weaken the substrate along the planar implantation zone. A main portion of the substrate above the planar implantation zone is separated from the device wafer assembly to form a thinned device wafer assembly. A residual portion of the substrate is removed from the thinned device wafer assembly to form a precursor.

In one embodiment, a mold compound layer is provided over the device layer of the device wafer assembly.

In one embodiment, the carrier wafer assembly is debonded from the precursor via the adhesive layer.

In one embodiment, the process further comprises providing a mold compound layer over the device layer of the device wafer assembly; and debonding the carrier wafer assembly from the precursor via the adhesive layer.

In one embodiment, the process further comprises providing at least one passivation layer over the device layer prior to providing the mold compound layer such that the at least one passivation layer resides between the mold compound layer and the device layer.

In one embodiment, at least one passivation layer comprises a first passivation layer over the device layer, and a second passivation layer over the first passivation layer. The first passivation layer may comprise silicon dioxide, and the second passivation layer may comprise silicon nitride.

In one embodiment, providing the device wafer assembly comprises providing the substrate with the device layer on the substrate; and implanting the substrate with an implant material to form the planar implantation zone wherein implantation occurs through the device layer. The device layer may be a complementary metal oxide semiconductor (CMOS) device structure that provides at least one CMOS device.

In one embodiment, providing the device wafer assembly comprises providing the substrate; implanting the substrate with an implant material to form the planar implantation zone before the device layer is provided on the substrate; and providing the device layer on the substrate. The device layer may be a complementary metal oxide semiconductor (CMOS) device structure that provides at least one CMOS device.

In one embodiment, the implant material comprises hydrogen.

In one embodiment, the planar implantation zone is between four (4) and twenty (20) nanometers below a top surface of the device layer.

In one embodiment, the substrate comprises silicon or glass.

In one embodiment, a semiconductor device formed from a method comprising providing a carrier wafer assembly; providing a device wafer assembly that comprises a substrate, a device layer on the substrate, wherein the device layer has at least one semiconductor device formed therein, and the substrate has a planar implantation zone below the device layer; bonding the carrier wafer assembly to the device layer of the device wafer assembly with an adhesive; annealing the substrate to weaken the substrate along the planar implantation zone; separating a main portion of the substrate above the planar implantation zone from the device wafer assembly to form a thinned device wafer assembly; and removing a residual portion of the substrate from the thinned device wafer assembly to form a precursor.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A through 1F illustrate an exemplary wafer fabrication process according to one embodiment of the disclosure.

FIG. 2 is a cross section of a wafer with a microcrack along a planar implantation zone according to one embodiment of the disclosure.

FIGS. 3A-3B illustrate an alternate process according to a second embodiment of the disclosure.

FIG. 4 is a block diagram of a communication system.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In the present disclosure, a novel approach is provided to separate the device layer from the substrate of a device wafer assembly with high precision. In a complementary metal oxide semiconductor (CMOS) application, the approach is used to separate the CMOS device layer from a silicon (Si) substrate of a device wafer assembly. The approach enables processing of the backside of the device layer with alternative materials to boost performance. The ability to expose the backside of the device layer and process it with different non-silicon (Si) material systems offers the opportunity to manipulate the device characteristics toward next generation technology requirements while reducing manufacturing costs. The following description uses a CMOS environment to illustrate the concepts presented herein, but those skilled in the art will recognize the applicability to other material systems.

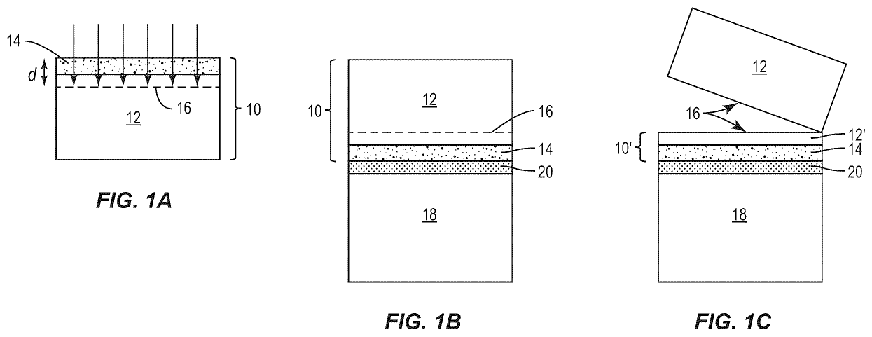

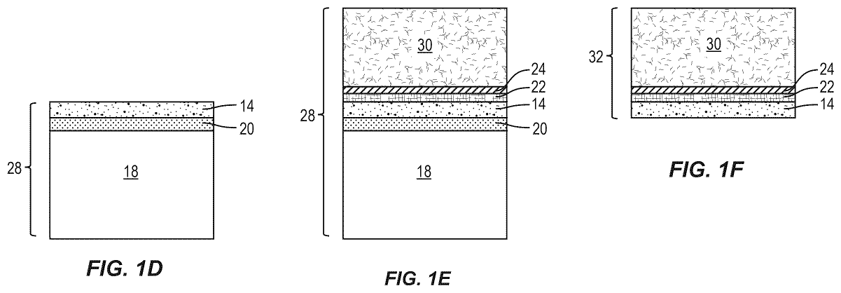

A fabrication process according to one embodiment of the invention is described in association with FIGS. 1A through 1F. With reference to FIG. 1A, a device wafer assembly 10 is provided. Those skilled in the art will appreciate that the device wafer assembly 10 will generally include a substrate 12 and a device layer 14. The substrate 12 is typically formed from silicon (Si), silicon dioxide (SiO₂), and the like, while the device layer 14 may be formed from one or more metal layers and semiconductor material in which one or more semiconductor devices and/or circuits are formed. In one embodiment, the device layer 14 may be a substantially or fully processed CMOS (complementary metal oxide semiconductor) structure that provides any number of CMOS devices, circuits, and the like. A CMOS structure may include a source region, drain region, gate structure, shallow trench isolation (STI) regions, interlayer dielectric (ILD) layers, and the like as those skilled in the art will appreciate. The device layer 14 of a CMOS structure typically has a thickness of 0.2 to 4 microns but may extend outside of this range. As defined herein, the device layer 14 may also include one or more interconnects to facilitate external connection for the above-mentioned semiconductor devices and/or circuits.

The device wafer assembly 10 is implanted with hydrogen (H), or the like, to form a planar implantation zone 16 below the device layer 14 and within the substrate 12. In this embodiment, the implantation is provided through the device layer 14 and into the substrate 12. The planar implantation zone 16 is represented by a dashed line and defines a plane at which the substrate 12 will be severed (or cut) into two sections during a subsequent processing step. In certain embodiments, the depth d of the planar implantation zone 16 ranges from 0.2 to 10 microns, 0.5 to 5 microns, 0.8 to 1.2 microns, and 0.3 to 5 microns, as illustrated in FIG. 1A, wherein the depth is measured from the top of the device layer 14 without including interconnecting structures.

The process continues by bonding the device wafer assembly 10 to a carrier wafer assembly 18 with an adhesive layer 20, as illustrated in FIG. 1B. In particular, the device layer 14 of the device wafer assembly 10 is inverted and directly or indirectly bonded to the carrier wafer assembly 18 with or without intervening layers (not shown) using the adhesive layer 20. The adhesive layer 20 may be formed from organic polymer materials, inorganic materials, or the like. An exemplary adhesive is adhesive BB305 from Brewer Science of Rolla, MO. The carrier wafer assembly 18 may be formed from silicon (Si), glass, non-silicon glass, or the like.

Once the device wafer assembly 10 and the carrier wafer assembly 18 are bonded together, a majority of the substrate 12 above the implantation zone 16 is removed from the backside of the device wafer assembly 10, as illustrated in FIG. 1C. A residual portion of the substrate 12 remains and is referred to as a thinned substrate 12′.

In one embodiment, the removal of a portion of the substrate 12 is facilitated by initially annealing, or heating, the combined device wafer assembly 10 and the carrier wafer assembly 18 to a temperature sufficient to structurally weaken the substrate 12 of the device wafer assembly 10 along the planar implantation zone 16. In one embodiment, the annealing is provided at 400 Celsius (C) for approximately one hour. During the annealing process, a very specific type of platelet structure is formed along the planar implantation zone 16 in the substrate 12, which eventually leads to blistering along the planar implantation zone 16. Once the blistering occurs, known cleavage techniques may be used to separate or simply remove the backside portion of the substrate 12 from the device wafer assembly 10 to form a thinned device wafer 10′, as shown in FIG. 1C. The thinned device wafer 10′ includes the device layer 14 and the thinned substrate 12′.

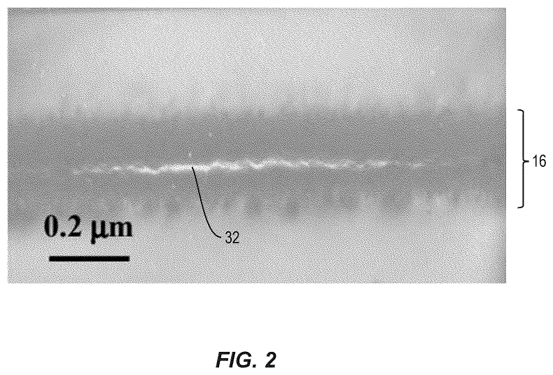

FIG. 2 is a transmission electron microscopy (TEM) image that shows the blistering or microcracking 16′ along the planar implantation zone 16 within the substrate 12 after annealing. The annealing temperature may occur around 350 Celsius. Annealing ranges are generally kept low to avoid damaging the semiconductor device and/or circuitry formed within the device layer 14. In certain embodiments, the annealing temperatures are kept at or below 400 Celsius. The process of creating the planar implantation zone 16 and using an annealing process to effectively generate a microcrack at which the respective pieces of a material can be separated is referred to as a smart-cut process.

Next, the back side of the thinned device assembly 10′ may be polished to remove some or all of the thinned substrate 12′ using known polishing and/or grinding techniques, such as chemical-mechanical polishing (CMP), wet etching, or the like, as illustrated in FIG. 1D. At this point, a precursor 28 is provided with the carrier wafer assembly 18, the adhesive layer 20, and the device layer 14.

Next, back-side processing commences and may include providing first and second passivation layers 22, 24, over the back side of the device layer 14 and a mold compound 30 over the first and second passivation layers 22, 24, as illustrated in FIG. 1E. The first passivation layer 22 may be Silicon Dioxide (SiO₂) or a variant thereof (SiOₓ), and the second passivation layer 24 may be Silicon Nitride (SiN). In other embodiments, one, two, or more passivation layers may be employed and may be formed from SiO₂, SiN, or the like, as those skilled in the art will appreciate. The mold compound 30 may be formed from an epoxy, or the like, as those skilled in the art will appreciate.

As illustrated in FIG. 1F, the carrier wafer assembly 18 is de-bonded and separated from the device layer 14 to generate a final device assembly 32. The debonding process entails breaking down the bond between the device layer 14 and the carrier wafer assembly 18 provided by the adhesive layer 20.

The front side of the final device assembly 32 may be polished to remove any residue of the carrier wafer 12. The final device assembly 32 may proceed to a passivation opening process to reveal the top metal layer, followed by forming typical redistribution metal layers and/or bumping processes (solder bump, copper (Cu) pillar bump, wafer level chip scale package (WLCSP) bump), as needed, and then singulation to separate the final device assembly 32 into individual components.

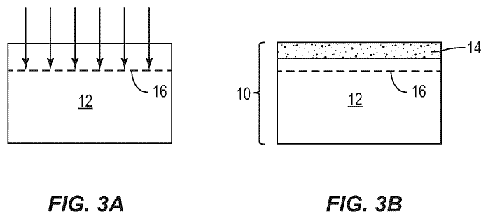

An alternative initiation of the above process is shown in FIGS. 3A and 3B. In the above process, the implantation zone 16 is created after the device layer 14 is formed on the substrate 12. For the alternative, the implantation zone 16 is created before the device layer 14 is formed on the substrate 12. Accordingly, the substrate 12 is implanted with hydrogen or the like to form the planar implantation zone 16 below the top surface of the substrate 12, as illustrated in FIG. 3A. Next, the device layer 14 is formed on the top surface of the substrate 12 to create the device wafer assembly 10, as illustrated in FIG. 3B. After this, the process associated with FIGS. 1B through 1F is provided.

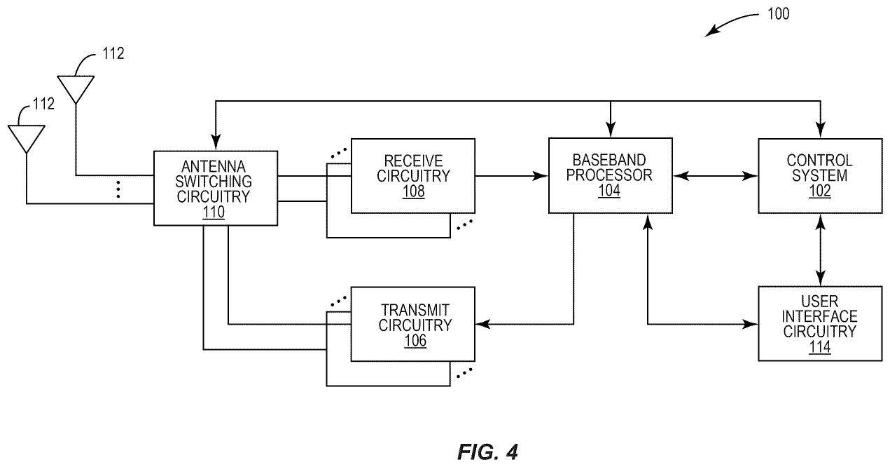

With reference to FIG. 4, the concepts described above may be implemented in various types of communication systems 100, such as mobile terminals, user elements, smart watches, tablets, personal computers, navigation devices, access points, and like wireless communication devices that support wireless communications, such as cellular, wireless local area network (WLAN), Bluetooth, and near field communications. The communication system 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA) or an application-specific integrated circuit (ASIC), as an example. The above components may be incorporated in active devices, integrated circuits, and the like that are formed using the concepts described above. Such components may also be incorporated into other types of electrical devices and systems, which should be appreciated by those skilled in the art.

The control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal through the antenna switching circuitry 110 to the antennas 112. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

What is claimed is:

1. A method comprising:
providing a carrier wafer assembly;
providing a device wafer assembly that comprises a substrate and a device layer on the substrate, wherein the device layer has at least one semiconductor device formed therein, and the substrate has a planar implantation zone of implant material below the device layer;
bonding the carrier wafer assembly to the device layer of the device wafer assembly with an adhesive layer;
annealing the substrate to weaken the substrate along the planar implantation zone;
separating a main portion of the substrate above the planar implantation zone from the device wafer assembly to form a thinned device wafer assembly; and
removing a residual portion of the substrate from the thinned device wafer assembly to form a precursor.

2. The method of claim 1 further comprising providing a mold compound layer over the device layer of the device wafer assembly.

3. The method of claim 1 further comprising debonding the carrier wafer assembly from the precursor via the adhesive layer.

4. The method of claim 1 further comprising:
providing a mold compound layer over the device layer of the device wafer assembly; and
debonding the carrier wafer assembly from the precursor via the adhesive layer.

5. The method of claim 4 further comprising providing at least one passivation layer over the device layer prior to providing the mold compound layer, such that the at least one passivation layer resides between the mold compound layer and the device layer.

6. The method of claim 5 wherein the at least one passivation layer comprises a first passivation layer over the device layer, and a second passivation layer over the first passivation layer.

7. The method of claim 6 wherein the first passivation layer comprises silicon dioxide, and the second passivation layer comprises silicon nitride.

8. The method of claim 4 wherein providing the device wafer assembly comprises:
providing the substrate with the device layer on the substrate; and
implanting the substrate with the implant material to form the planar implantation zone wherein implantation occurs through the device layer.

9. The method of claim 8 wherein the device layer is a complementary metal oxide semiconductor (CMOS) device structure that provides at least one CMOS device.

10. The method of claim 4 wherein providing the device wafer assembly comprises:
providing the substrate;
implanting the substrate with the implant material to form the planar implantation zone before the device layer is provided on the substrate; and
providing the device layer on the substrate.

11. The method of claim 10 wherein the device layer is a complementary metal oxide semiconductor (CMOS) device structure that provides at least one CMOS device.

12. The method of claim 1 wherein the device layer is a complementary metal oxide semiconductor (CMOS) device structure that provides at least one CMOS device.

13. The method of claim 1 wherein the implant material comprises hydrogen.

14. The method of claim 8 wherein the planar implantation zone is between four (4) and twenty (20) nanometers below a top surface of the device layer.

15. The method of claim 1 wherein the substrate comprises silicon.

16. The method of claim 1 wherein the substrate comprises glass.

17. The method of claim 1 further comprising singulating the precursor.

18. A semiconductor device formed from a method comprising:
providing a carrier wafer assembly;
providing a device wafer assembly that comprises a substrate and a device layer on the substrate, wherein the device layer has at least one semiconductor device formed therein, and the substrate has a planar implantation zone of implant material below the device layer;
bonding the carrier wafer assembly to the device layer of the device wafer assembly with an adhesive layer;
annealing the substrate to weaken the substrate along the planar implantation zone;
separating a main portion of the substrate above the planar implantation zone from the device wafer assembly to form a thinned device wafer assembly; and
removing a residual portion of the substrate from the thinned device wafer assembly to form a precursor.

19. The semiconductor device of claim 18 wherein the substrate comprises at least one of glass and silicon.

20. A communication device comprising a semiconductor device formed from a method comprising:
providing a carrier wafer assembly;
providing a device wafer assembly that comprises a substrate and a device layer on the substrate, wherein the device layer has at least one semiconductor device formed therein, and the substrate has a planar implantation zone of implant material below the device layer;
bonding the carrier wafer assembly to the device layer of the device wafer assembly with an adhesive layer;
annealing the substrate to weaken the substrate along the planar implantation zone;
separating a main portion of the substrate above the planar implantation zone from the device wafer assembly to form a thinned device wafer assembly; and
removing a residual portion of the substrate from the thinned device wafer assembly to form a precursor.
